(19) United States
(12) Patent Application Publication
(10) Pub. No.: US 2018/0301406 A1
(43) Pub. Date: Oct. 18, 2018

(54) SEMICONDUCTOR PACKAGE AND METHOD FOR MANUFACTURING THE SAME

(71) Applicant: SAMSUNG ELECTRONICS CO., LTD., Suwon-si (KR)

(72) Inventors: JAEMIN CHO, Yongin-si (KR); HEEJU SEO, Asan-si (KR); SUNGBOK HONG, Cheonan-si (KR)

(21) Appl. No.: 15/854,911

(22) Filed: Dec. 27, 2017

(30) Foreign Application Priority Data
Apr. 18, 2017 (KR) 10-2017-0049702

(51) Int. Cl. H01L 23/498; H01L 23/31; H01L 25/10; H01L 23/00; H01L 21/48; H01L 21/56; H01L 25/065

(52) U.S. Cl. CPC H01L 23/49833; H01L 2225/06586; H01L 23/3128; H01L 23/3135; H01L 25/105; H01L 24/16; H01L 24/32; H01L 24/73; H01L 24/81; H01L 21/4853; H01L 21/565; H01L 25/0657; H01L 2225/1058; H01L 2225/1023; H01L 2224/16227; H01L 2224/32225; H01L 2224/73204; H01L 2224/14135; H01L 2224/13014; H01L 24/13; H01L 24/14; H01L 24/48; H01L 2224/48091; H01L 2224/48106; H01L 2224/48227; H01L 2224/81191; H01L 2225/0651; H01L 2225/06517; H01L 2225/0652; H01L 2225/06572; H01L 23/49816

(57) ABSTRACT

A semiconductor package includes a first semiconductor chip positioned above a first substrate. A second substrate is positioned above the first substrate. The first semiconductor chip is positioned between the first substrate and the second substrate. A plurality of support structures are disposed between the second substrate and the first semiconductor chip. Connection members are disposed between the first substrate and the second substrate. The connection members electrically connect the first substrate to the second substrate. A molding layer fills a space between the first substrate and the second substrate. The molding layer is disposed on the first semiconductor chip and the connection members.

### CROSS-REFERENCE TO RELATED APPLICATION

This U.S. non-provisional patent application claims priority under 35 U.S.C. § 119 to Korean Patent Application No. 10-2017-0049702, filed on Apr. 18, 2017, in the Korean Intellectual Property Office, the disclosure of which is incorporated by reference herein in its entirety.

### TECHNICAL FIELD

Exemplary embodiments of the present inventive concept relate to a semiconductor package, and more particularly to a method for manufacturing the same.

### DISCUSSION OF RELATED ART

High-performance, high-speed and small electronic components have been developed. A packaging technique for embodying a plurality of semiconductor chips or a plurality of semiconductor packages in one package has also been developed.

### SUMMARY

An exemplary embodiment of the present inventive concept provides a semiconductor package with increased reliability.

An exemplary embodiment of the present inventive concept provides a method for manufacturing a semiconductor package with increased reliability.

An exemplary embodiment of the present inventive concept provides a method for manufacturing a semiconductor package, which is capable of simplifying manufacturing processes.

In an exemplary embodiment of the present inventive concept, a semiconductor package includes a first semiconductor chip positioned above a first substrate. A second substrate is positioned above the first substrate. The first semiconductor chip is positioned between the first substrate and the second substrate. A plurality of support structures are disposed between the second substrate and the first semiconductor chip. Connection members are disposed between the first substrate and the second substrate. The connection members electrically connect the first substrate to the second substrate. A molding layer fills a space between the first substrate and the second substrate. The molding layer is disposed on the first semiconductor chip and the connection members.

In an exemplary embodiment of the present inventive concept, a semiconductor package includes a first semiconductor chip positioned above a first substrate. A second substrate is positioned above the first substrate. A support structure is positioned between the second substrate and the first semiconductor chip. A connection member electrically connects the first substrate to the second substrate. A molding layer fills a space between the first substrate and the second substrate. The molding layer is disposed on the first semiconductor chip and the connection member. A width of the support structure along a direction parallel to a surface of the first substrate facing the second substrate ranges from about 1/200 to about 1/10 of a width of the first semiconductor chip along the direction parallel to the surface of the first substrate facing the second substrate.

In an exemplary embodiment of the present inventive concept, a method for manufacturing a semiconductor package includes mounting a first semiconductor chip above a first substrate. A second substrate is positioned above the first substrate. The second substrate includes a support structure disposed on a bottom surface of the second substrate and vertically overlapping with the first semiconductor chip along a direction orthogonal to a surface of the first substrate facing the second substrate. The method includes performing a reflow process to form a connection member electrically connecting the first substrate to the second substrate, and forming a molding layer covering the first semiconductor chip and a sidewall of the connection member.

In an exemplary embodiment of the present inventive concept, a semiconductor package includes a first substrate and a semiconductor chip positioned above the first substrate. A second substrate is positioned above the semiconductor chip. A support structure is disposed on an upper surface of the semiconductor chip facing the second substrate. A bottom surface of the support structure is in direct contact with the upper surface of the semiconductor chip facing the second substrate. A top surface of the support structure is in direct contact with a bottom surface of the second substrate facing the semiconductor chip. A plurality of connection members are disposed between the first substrate and the second substrate. At least one connection member of the plurality of connection members electrically connects the first substrate and the second substrate to each other. A molding layer is formed between the first substrate and the second substrate. The molding layer surrounds the semiconductor chip.

### BRIEF DESCRIPTION OF THE DRAWINGS

The above and other features of the inventive concept will become more apparent by describing in detail exemplary embodiments thereof, with reference to the accompanying drawings, in which:

FIG. 1 is a schematic plan view illustrating a semiconductor package according to an exemplary embodiment of the present inventive concept.

FIG. 2A is a cross-sectional view illustrating a semiconductor package according to an exemplary embodiment of the present inventive concept.

FIG. 2B is a cross-sectional view illustrating a semiconductor package according to an exemplary embodiment of the present inventive concept.

FIG. 3 is a schematic plan view illustrating a semiconductor package according to an exemplary embodiment of the present inventive concept.

FIG. 4A is a cross-sectional view illustrating a stack-type semiconductor package according to an exemplary embodiment of the present inventive concept.

FIG. 4B is a cross-sectional view illustrating a stack-type semiconductor package according to an exemplary embodiment of the present inventive concept.

FIGS. 5A, 5B, 5C, 5D, 5E, 5F and 5G are cross-sectional views illustrating a method for manufacturing a semiconductor package according to an exemplary embodiment of the present inventive concept.

FIG. 6 is a cross-sectional view illustrating a method for manufacturing a semiconductor package according to an exemplary embodiment of the present inventive concept.

### DETAILED DESCRIPTION OF THE EMBODIMENTS

Exemplary embodiments of the present inventive concept will be described below in more detail with reference to the accompanying drawings. In this regard, the present inventive concept may have different forms and should not be construed as being limited to the exemplary embodiments of the present inventive concept described herein. Like reference numerals may refer to like elements throughout the specification and drawings.

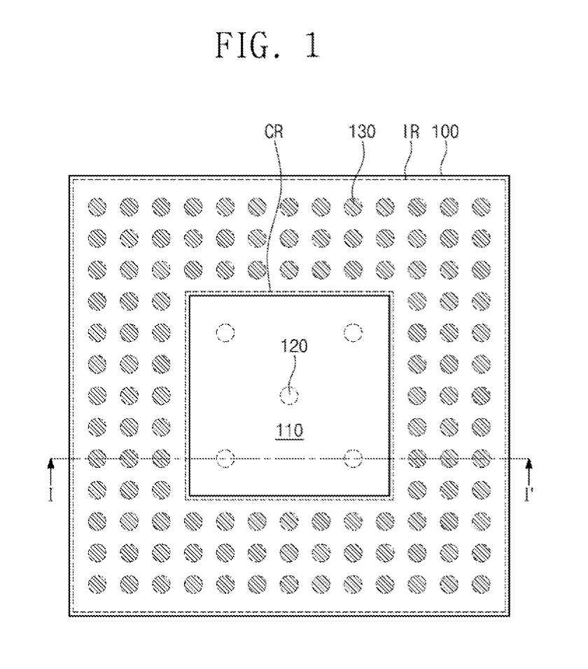

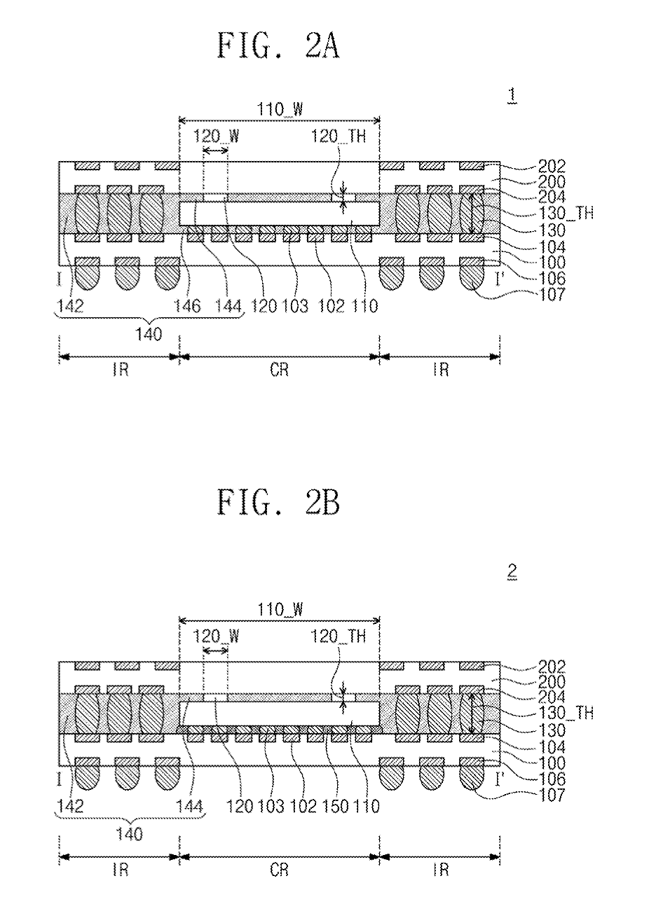

FIG. 1 is a schematic plan view illustrating a semiconductor package according to an exemplary embodiment of the present inventive concept. FIG. 2A is a cross-sectional view illustrating a semiconductor package according to an exemplary embodiment of the present inventive concept. FIG. 2A is a cross-sectional view corresponding to a line I-I′ of FIG. 1.

Referring to FIGS. 1 and 2A, a semiconductor package 1 may include a first substrate 100, a first semiconductor chip 110, at least one support structure 120, connection members 130, a first molding layer 140, and a second substrate 200.

The first substrate 100 may include a central chip region CR and a connection region IR around the chip region CR when viewed in a plan view. For example, the first substrate 100 may be a printed circuit board that includes circuit patterns therein.

The first substrate 100 may include first chip pads 102, first connection pads 104, and external connection pads 106. The first chip pads 102 and the first connection pads 104 may be positioned at a top surface of the first substrate 100. For example, the first chip pads 102 may be positioned at a top surface of the first substrate 100 in the chip region CR, and the first connection pads 104 may be positioned at a top surface of the first substrate 100 in the connection region IR. The external connection pads 106 may be positioned at a bottom surface of the first substrate 100. Chip bumps 103 may be disposed on the first chip pads 102, respectively. External connection solder balls 107 may be disposed on the external connection pads 106, respectively. The first substrate 100 may be electrically connected to an external electronic device through the external connection solder balls 107. The Chip bumps 103 and the external connection solder balls 107 may include a conductive material (e.g., a metal).

The first semiconductor chip 110 may be positioned above the first substrate 100 in the chip region CR. The first semiconductor chip 110 may be mounted above the first substrate 100 by a flip chip bonding method. For example, the first semiconductor chip 110 may be electrically connected to the first substrate 100 through the chip bumps 103. The first semiconductor chip 110 may include an integrated circuit (e.g., a logic circuit).

The second substrate 200 may be positioned above the first substrate 100. The first semiconductor chip 110 may be positioned between the first substrate 100 and the second substrate 200. For example, the second substrate 200 may be a printed circuit board that includes circuit patterns therein.

The second substrate 200 may include upper pads 202 and second connection pads 204. The upper pads 202 may be positioned at a top surface of the second substrate 200, and the second connection pads 204 may be positioned at a bottom surface of the second substrate 200. For example, the second connection pads 204 may be positioned to correspond to the first connection pads 104, respectively, when viewed in a plan view.

The at least one support structure 120 may be disposed between the first semiconductor chip 110 and the second substrate 200. According to an exemplary embodiment of the present inventive concept, the support structure 120 may include a plurality of support structures 120 (see, e.g., FIGS. 1 and 2A). According to an exemplary embodiment of the present inventive concept, one support structure 120 may be positioned between the first semiconductor chip 110 and the second substrate 200 (see, e.g., FIG. 3). An exemplary embodiment of the present inventive concept in which the plurality of support structures 120 is provided will be described in more detail below; however, exemplary embodiments of the present inventive concept are not limited thereto.

The support structures 120 may be spaced apart from each other when viewed in a plan view. For example, the support structures 120 may be spaced apart from each other along a direction parallel to an upper surface of the first substrate 100 facing the second substrate 200. The minimum distance between the support structures 120 along the direction parallel to the upper surface of the first substrate 100 facing the second substrate 200 may be about 300 μm or more. According to an exemplary embodiment of the present inventive concept, the support structures 120 may be disposed adjacent to corner portions and a central portion of the first semiconductor chip 110 when viewed in a plan view. However, exemplary embodiments of the present inventive concept are not limited thereto. In an exemplary embodiment of the present inventive concept, the planar arrangement of the support structures 120 may be variously modified or changed.

A width 120_W of each of the support structures 120 in one direction (e.g., along the direction parallel to the upper surface of the first substrate 100 facing the second substrate 200) may range from about 1/200 to about 1/10 of a width 110_W of the first semiconductor chip 110 in the one direction (e.g., along the direction parallel to the upper surface of the first substrate 100 facing the second substrate 200). For example, the width 120_W of each of the support structures 120 in the one direction may range from about 30 μm to about 600 μm.

A thickness 120_TH of each of the support structures 120 along a direction orthogonal to the upper surface of the first substrate 100 facing the second substrate 200 may range from about 1/10 to about ⅖ of a thickness 130_TH of the connection member 130 along the direction orthogonal to the upper surface of the first substrate 100 facing the second substrate 200. The connection member 130 will be described in more detail below. For example, the thickness 120_TH of each of the support structures 120 along the direction orthogonal to the upper surface of the first substrate 100 facing the second substrate 200 may range from about 20 μm to about 100 μm.

A top surface of each of the support structures 120 may be in direct contact with the second substrate 200, and a bottom surface of each of the support structures 120 may be in direct contact with the first semiconductor chip 110. Thus, a space having a substantially uniform height along the direction orthogonal to the upper surface of the first substrate 100 facing the second substrate 200 (e.g., in a range of about 20 μm to about 100 μm) may be secured between the first semiconductor chip 110 and the second substrate 200 by the support structures 120.

The support structures 120 may include a polymer material. For example, the support structures 120 may include at least one of an epoxy resin, a die attach film (DAF), a non-conductive film (NCF), or a solder resist.

The connection members 130 may be disposed between the first substrate 100 and the second substrate 200. The connection members 130 may electrically connect the first and second substrates 100 and 200 to each other. For example, each of the connection members 130 may be disposed between a pair of the first connection pads 104 and the second connection pad 204 overlapping with each other in a plan view and may electrically connect the pair of the first and second connection pads 104 and 204 overlapping with each other along the direction orthogonal to the upper surface of the first substrate 100 facing the second substrate 200.

The connection members 130 may be positioned in the connection region IR of the first substrate 100. For example, the connection members 130 may be arranged around the first semiconductor chip 110 disposed on the chip region CR when viewed in a plan view. The connection members 130 may include a conductive material (e.g., a metal).

The first molding layer 140 may be formed between the first substrate 100 and the second substrate 200. The first molding layer 140 may surround the first semiconductor chip 110 and may be disposed on sidewalls of the connection members 130. For example, the first molding layer 140 may include an epoxy molding compound (EMC).

The first molding layer 140 may include a first portion 142 positioned in the connection region IR and a second portion 144 positioned in the chip region CR.

The first portion 142 may cover sidewalls of the connection members 130. A bottom surface of the first portion 142 may be in contact with the first substrate 100, and a top surface of the first portion 142 may be in contact with the second substrate 200.

The second portion 144 may extend from the first portion 142 into the space between the first semiconductor chip 110 and the second substrate 200. The second portion 144 may fill the space which is secured between the first semiconductor chip 110 and the second substrate 200 by the support structures 120. For example, the second portion 144 may extend between the support structures 120 spaced apart from each other. The second portion 144 may cover sidewalls of the support structures 120. A bottom surface of the second portion 144 may be in contact with the first semiconductor chip 110, and a top surface of the second portion 144 may be in contact with the second substrate 200.

In an exemplary embodiment of the present inventive concept, the first molding layer 140 may further include a third portion 146 positioned in the chip region CR. The third portion 146 may extend from the first portion 142 into a space between the first substrate 100 and the first semiconductor chip 110. The third portion 146 may be disposed on side surfaces of the chip bumps 103. A bottom surface of the third portion 146 may be in contact with the first substrate 100, and a top surface of the third portion 146 may be in contact with the first semiconductor chip 110.

In an exemplary embodiment of the present inventive concept, a semiconductor package may include the first substrate 100 and the semiconductor chip 110 positioned above the first substrate 100. The second substrate 200 may be positioned above the semiconductor chip 110. The support structure 120 may be disposed on an upper surface of the semiconductor chip 110 facing the second substrate 200. A bottom surface of the support structure 120 may be in direct contact with the upper surface of the semiconductor chip 110 facing the second substrate 200. A top surface of the support structure 120 may be in direct contact with a bottom surface of the second substrate 200 facing the semiconductor chip 110. A plurality of connection members 130 may be disposed between the first substrate 100 and the second substrate 200. At least one connection member of the plurality of connection members 130 may electrically connect the first substrate 100 and the second substrate 200 to each other. The molding 140 layer may be formed between the first substrate 100 and the second substrate 200. The molding layer 140 may surround the semiconductor chip 110.

In an exemplary embodiment of the present inventive concept, the first molding layer 140 need not include the third portion 146.

FIG. 2B is a cross-sectional view illustrating a semiconductor package according to an exemplary embodiment of the present inventive concept. FIG. 2B is a cross-sectional view corresponding to the line I-I′ of FIG. 1. Referring to FIGS. 1 and 2B below, the same elements as described with reference to FIGS. 1 and 2A will be indicated by the same reference numerals or the same reference designators, and thus the descriptions thereof may be omitted or mentioned briefly below.

Referring to FIGS. 1 and 2B, a semiconductor package 2 may include the first substrate 100, the first semiconductor chip 110, at least one support structure 120, connection members 130, the first molding layer 140, and a second substrate 200. The first substrate 100, the first semiconductor chip 110, the at least one support structure 120, the connection members 130, and the second substrate 200 may be substantially the same as described with reference to FIGS. 1 and 2A.

The semiconductor package 2 may further include an underfill layer 150. The underfill layer 150 may be formed between the first substrate 100 and the first semiconductor chip 110 and may cover side surfaces of the chip bumps 103. A bottom surface of the underfill layer 150 may be in contact with the first substrate 100, and a top surface of the underfill layer 150 may be in contact with the first semiconductor chip 110. For example, the underfill layer 150 may include an underfill epoxy.

The first molding layer 140 may include the first portion 142 and the second portion 144. The first portion 142 and the second portion 144 may be substantially the same as described with reference to FIGS. 1 and 2A. The first molding layer 140 need not include the third portion 146 described with reference to FIGS. 1 and 2A.

FIG. 3 is a schematic plan view illustrating a semiconductor package according to an exemplary embodiment of the present inventive concept.

Referring to FIG. 3, a semiconductor package 3 may be similar to the semiconductor package 1 described with reference to FIGS. 1 and 2A or the semiconductor package 2 described with reference to FIGS. 1 and 2B, and thus duplicative descriptions may be omitted below. For example, except for planar arrangement and the number of the support structure 120, the semiconductor package 3 may be substantially the same as the semiconductor package 1 or the semiconductor package 2.

The semiconductor package 3 may include one support structure 120. The support structure 120 may be disposed at a central portion of the first semiconductor chip 110 when viewed in a plan view.

The semiconductor packages 1, 2, or 3 according to an exemplary embodiment of the present inventive concept may include the at least one support structure 120 disposed between the first semiconductor chip 110 and the second substrate 200. The space having the substantially uniform height (e.g., in a range of about 20 μm to about 100 μm) may be secured between the first semiconductor chip 110 and the second substrate 200 by the at least one support structure 120. Thus, the first molding layer 140 may evenly fill the space between the first semiconductor chip 110 and the second substrate 200 without a void (or an air gap). Thus, according to an exemplary embodiment of the present inventive concept, the semiconductor packages 1, 2, or 3 with increased reliability may be provided.

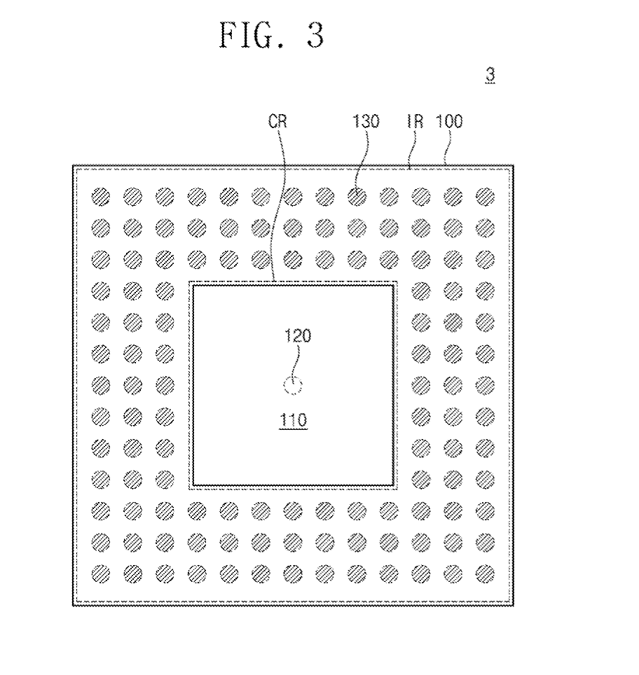

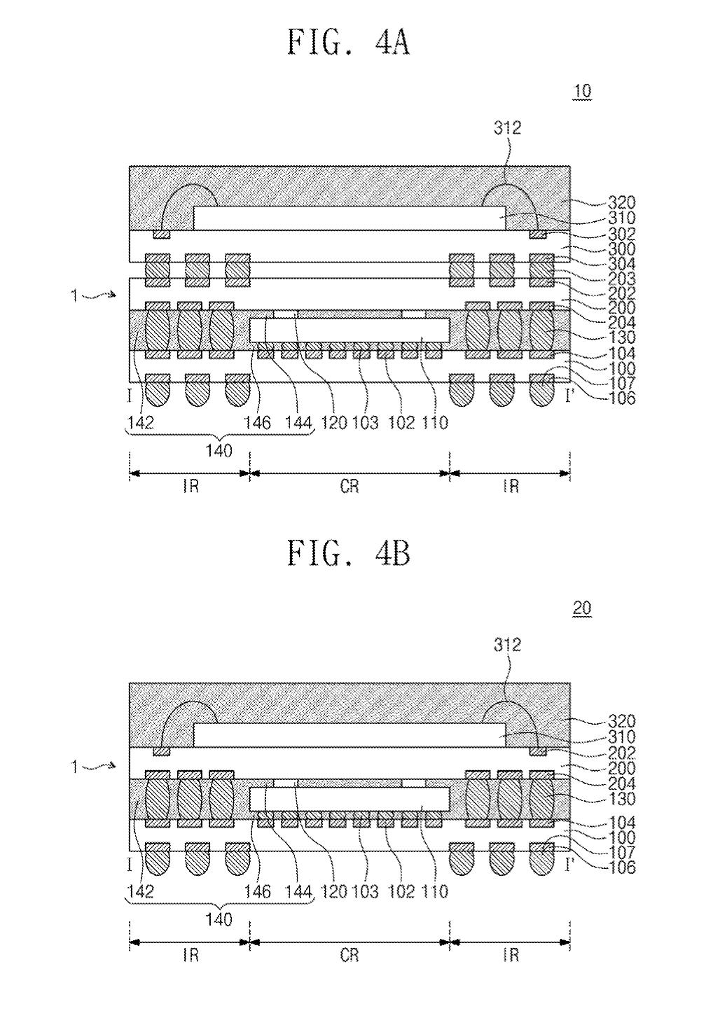

FIG. 4A is a cross-sectional view illustrating a stack-type semiconductor package according to an exemplary embodiment of the present inventive concept.

Referring to FIG. 4A, a stack-type semiconductor package 10 may include the semiconductor package 1, a third substrate 300, a second semiconductor chip 310, and a second molding layer 320.

The semiconductor package 1 may be substantially the same as described with reference to FIGS. 1 and 2A, and thus duplicative descriptions may be omitted below. The semiconductor package 1 may be replaced with the semiconductor package 2 described with reference to FIGS. 1 and 2B or the semiconductor package 3 described with reference to FIG. 3.

The third substrate 300 may be positioned above the semiconductor package 1. The third substrate 300 may include second chip pads 302 and third connection pads 304. The second chip pads 302 may be positioned at a top surface of the third substrate 300, and the third connection pads 304 may be positioned at a bottom surface of the third substrate 300. For example, the third connection pads 304 may be positioned to correspond to the upper pads 202 of the second substrate 200, respectively, when viewed in a plan view (e.g., along the direction orthogonal to the upper surface of the first substrate 100 facing the second substrate 200). For example, the third substrate 300 may be a printed circuit board that includes circuit patterns therein.

Additional connection members 203 may be positioned between the second substrate 200 and the third substrate 300. The additional connection members 203 may electrically connect the second substrate 200 to the third substrate 300. For example, each of the additional connection members 203 may be positioned between a pair of the upper pad 202 and the third connection pad 304 overlapping with each other in a plan view (e.g., along the direction orthogonal to the upper surface of the first substrate 100 facing the second substrate 200) and may electrically connect the pair of upper pad 202 and the third connection pad 304 to each other. The additional connection members 203 may include a conductive material (e.g., a metal).

The second semiconductor chip 310 may be mounted on the third substrate 300. In an exemplary embodiment of the present inventive concept, the second semiconductor chip 310 may include a plurality of second semiconductor chips 310. In an exemplary embodiment of the present inventive concept, the plurality of second semiconductor chips 310 may be vertically stacked along the direction orthogonal to the upper surface of the first substrate 100 facing the second substrate 200 or may be laterally arranged along the direction parallel to the upper surface of the first substrate 100 facing the second substrate 200. The second semiconductor chip 310 may include an integrated circuit (e.g., a memory circuit).

According to an exemplary embodiment of the present inventive concept, the second semiconductor chip 310 may be mounted on the third substrate 300 by a wire bonding method (see, e.g., FIG. 4A). In an exemplary embodiment of the present inventive concept, bonding wires 312 may electrically connect the second semiconductor chip 310 to the second chip pads 302.

According to an exemplary embodiment of the present inventive concept, the second semiconductor chip 310 may be mounted on the third substrate 300 by a flip chip bonding method. In an exemplary embodiment of the present inventive concept, the second semiconductor chip 310 may be electrically connected to the third substrate 300 through chip bumps.

The second molding layer 320 may be disposed on the third substrate 300. The second molding layer 320 may cover the top surface of the third substrate 300 and the second semiconductor chip 310. When the bonding wires 312 are provided (see, e.g., FIG. 4A), the second molding layer 320 may cover the bonding wires 312. For example, the second molding layer 320 may include an epoxy molding compound (EMC).

In an exemplary embodiment of the present inventive concept described with reference to FIG. 4A, the first substrate 100, the first semiconductor chip 110, and the first molding layer 140 may be included in a lower semiconductor package. The third substrate 300, the second semiconductor chip 310, and the second molding layer 320 may be included in an upper semiconductor package. The second substrate 200 may be an interposer substrate positioned between the lower semiconductor package and the upper semiconductor package.

FIG. 4B is a cross-sectional view illustrating a stack-type semiconductor package according to an exemplary embodiment of the present inventive concept.

Referring to FIG. 4B, a stack-type semiconductor package 20 may include the semiconductor package 1, the second semiconductor chip 310, and the second molding layer 320.

The semiconductor package 1 may be substantially the same as described with reference to FIGS. 1 and 2A, and thus duplicative descriptions may be omitted below. The semiconductor package 1 may be replaced with the semiconductor package 2 described with reference to FIGS. 1 and 2B or the semiconductor package 3 described with reference to FIG. 3.

The second semiconductor chip 310 may be mounted on the second substrate 200. In an exemplary embodiment of the present inventive concept, the second semiconductor chip 310 may include a plurality of second semiconductor chips 310. The second semiconductor chip 310 may include an integrated circuit (e.g., a memory circuit).

According to an exemplary embodiment of the present inventive concept, the second semiconductor chip 310 may be mounted on the second substrate 200 by a wire bonding method (see, e.g., FIG. 4B). In an exemplary embodiment of the present inventive concept, bonding wires 312 may electrically connect the second semiconductor chip 310 to the upper pads 202 of the second substrate 200.

According to an exemplary embodiment of the present inventive concept, the second semiconductor chip 310 may be mounted on the second substrate 200 by a flip chip bonding method. In an exemplary embodiment of the present inventive concept, the second semiconductor chip 310 may be electrically connected to the second substrate 200 through chip bumps.

The second molding layer 320 may be disposed on the second substrate 200. The second molding layer 320 may cover the top surface of the second substrate 200 and the second semiconductor chip 310. When the bonding wires 312 are provided (see, e.g., FIG. 4B), the second molding layer 320 may cover the bonding wires 312. For example, the second molding layer 320 may include an epoxy molding compound (EMC).

In an exemplary embodiment of the present inventive concept described with reference to FIG. 4B, the first substrate 100, the first semiconductor chip 110, and the first molding layer 140 may be included in a lower semiconductor package. The second substrate 200, the second semiconductor chip 310, and the second molding layer 320 may be included in an upper semiconductor package.

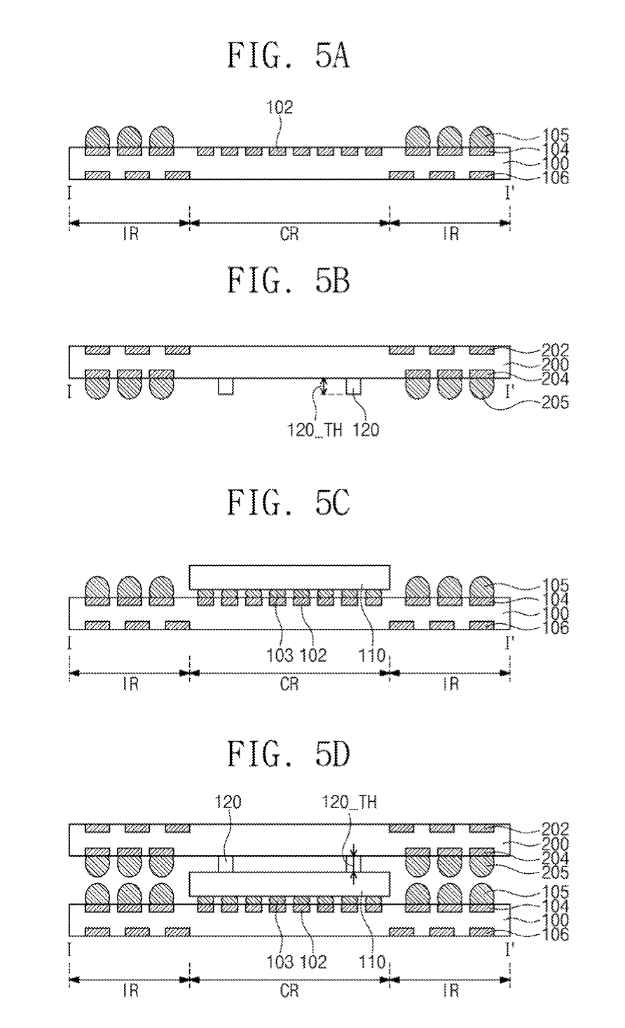

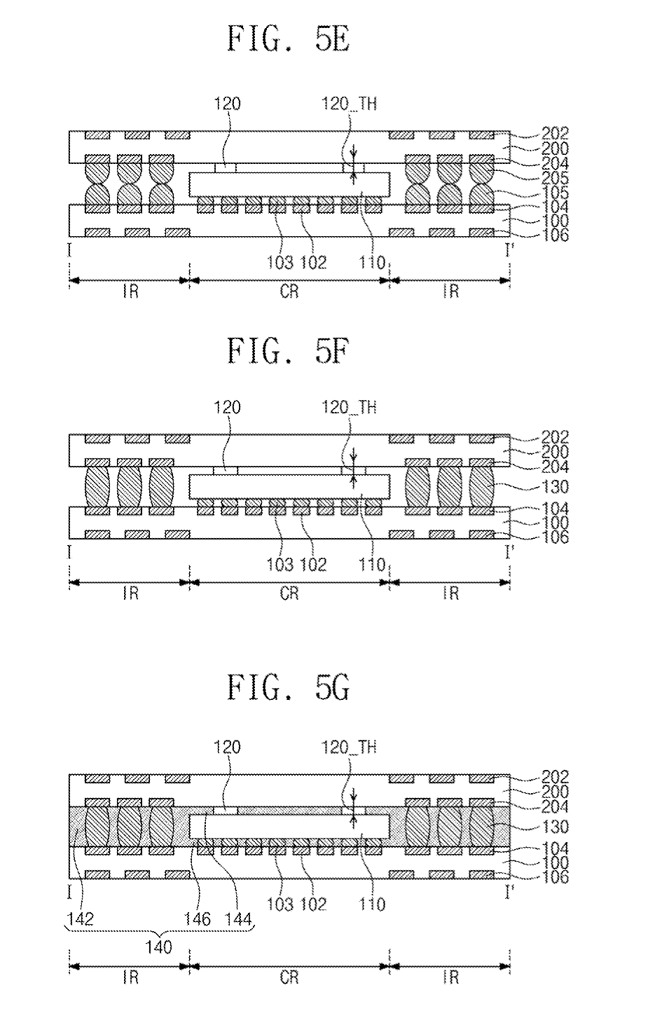

FIGS. 5A, 5B, 5C, 5D, 5E, 5F and 5G are cross-sectional views illustrating a method for manufacturing a semiconductor package according to an exemplary embodiment of the present inventive concept. FIGS. 5A to 5G are cross-sectional views corresponding to the line I-I′ of FIG. 1. A method for manufacturing a semiconductor package according to an exemplary embodiment of the present inventive concept will be described in more detail below with reference to FIGS. 5A to 5G. Referring to FIGS. 5A to 5B below, the same elements as described with reference to FIGS. 1 and 2A will be indicated by the same reference numerals or the same reference designators, and thus the descriptions thereof may be omitted or mentioned briefly below.

Referring to FIG. 5A, the first substrate 100 may be provided. The first substrate 100 may be substantially the same as the first substrate 100 described with reference to FIGS. 1 and 2A. First solder balls 105 may be formed on the first connection pads 104 of the first substrate 100, respectively.

Referring to FIG. 5B, the second substrate 200 may be provided. The second substrate 200 may be substantially the same as the second substrate 200 described with reference to FIGS. 1 and 2A. Second solder balls 205 may be formed on the second connection pads 204 of the second substrate 200, respectively.

At least one support structure 120 may be formed on the bottom surface of the second substrate 200. According to an exemplary embodiment of the present inventive concept, the support structure 120 may include a plurality of support structures 120 (see, e.g., FIG. 5B). According to an exemplary embodiment of the present inventive concept, one support structure 120 may be formed on the bottom surface of the second substrate 200. An exemplary embodiment of the present inventive concept in which the plurality of support structures 120 are formed will be described in more detail below; however, exemplary embodiments of the present inventive concept are not limited thereto.

Each of the support structures 120 may adhere to the bottom surface of the second substrate 200. As an example, a top surface of each of the support structures 120 may be in contact with the bottom surface of the second substrate 200. Each of the support structures 120 may have a thickness 120_TH along the direction orthogonal to the upper surface of the first substrate 100 facing the second substrate 200.

In an exemplary embodiment of the present inventive concept, the support structures 120 may include a polymer material having a glass transition temperature lower than melting points of the first and second solder balls 105 and 205. For example, the support structures 120 may include at least one of an epoxy resin, a die attach film (DAF), or a non-conductive film (NCF).

In an exemplary embodiment of the present inventive concept, the support structures 120 may include a polymer material having a glass transition temperature higher than the melting points of the first and second solder balls 105 and 205. For example, the support structures 120 may include a solder resist.

Referring to FIG. 5C, a first semiconductor chip 110 may be mounted above the chip region CR of the first substrate 100. The first semiconductor chip 110 may be mounted above the first substrate 100 by a flip chip bonding method. For example, the first semiconductor chip 110 may be electrically connected to the first chip pads 102 of the first substrate 100 through chip bumps 103.

In an exemplary embodiment of the present inventive concept, the underfill layer 150 may be formed (see, e.g., FIG. 2B). The underfill layer 150 may be injected between the first substrate 100 and the first semiconductor chip 110 to fill a space between the first substrate 100 and the first semiconductor chip 110. The underfill layer 150 may cover the chip bumps 103. In an exemplary embodiment of the present inventive concept, the process of forming the underfill layer 150 may be omitted.

Referring to FIG. 5D, the second substrate 200 may be positioned above the first substrate 100. Thus, the top surface of the first substrate 100 may face the bottom surface of the second substrate 200. The second solder balls 205 may correspond to or overlap with the first solder balls 105, respectively, when viewed in a plan view (e.g., along the direction orthogonal to the upper surface of the first substrate 100 facing the second substrate 200).

The support structures 120 may vertically overlap with the first semiconductor chip 110 along the direction orthogonal to the upper surface of the first substrate 100 facing the second substrate 200. As an example, the support structures 120 may overlap with the first semiconductor chip 110 when viewed in a plan view (e.g., along the direction orthogonal to the upper surface of the first substrate 100 facing the second substrate 200). The bottom surfaces of the support structures 120 may be in contact with the first semiconductor chip 110.

According to an exemplary embodiment of the present inventive concept, the second solder balls 205 may be vertically spaced apart from the first solder balls 105 along the direction orthogonal to the upper surface of the first substrate 100 facing the second substrate 200 (see, e.g., FIG. 5D). However, exemplary embodiments of the present inventive concept are not limited thereto. According to an exemplary embodiment of the present inventive concept, the second solder balls 205 may be in contact with the first solder balls 105.

Referring to FIGS. 5E and 5F, connection members 130 electrically connecting the first substrate 100 to the second substrate 200 may be formed. The formation of the connection members 130 may include performing a reflow process to melt and bond each of the first solder balls 105 and each of the second solder balls 205 corresponding to each other.

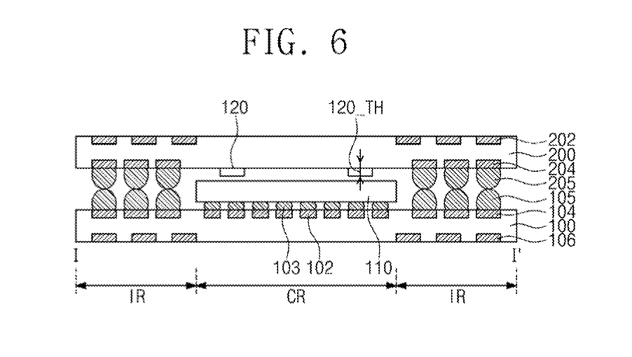

The reflow process in an exemplary embodiment of the present inventive concept in which the support structures 120 include the polymer material having the glass transition temperature lower than the melting points of the solder balls 105 and 205 will be described in more detail below. The reflow process in an exemplary embodiment of the present inventive concept in which the support structures 120 include the polymer material having the glass transition temperature higher than the melting points of the solder balls 105 and 205 will be described in more detail below with reference to FIG. 6.

Referring to FIG. 5E, heat energy may be provided during the reflow process. Thus, the support structures 120 and the first and second solder balls 105 and 205 may be heated.

The support structures 120 may be softened before the first and second solder balls 105 and 205 are melted. This may be because the support structures 120 include the polymer material having the glass transition temperature lower than the melting points of the first and second solder balls 105 and 205. Thus, the support structures 120 may be transformed in such a way that the thicknesses 120_TH of the support structures 120 are reduced.

When the second solder balls 205 are vertically spaced apart from the first solder balls 105 along the direction orthogonal to the upper surface of the first substrate 100 facing the second substrate 200 (see, e.g., FIG. 51)), the thicknesses 120_TH of the support structures 120 may be reduced such that the second solder balls 205 may come in contact with the first solder balls 105 corresponding thereto, respectively.

Referring to FIG. 5F, next, as the heat energy is continuously provided, the transformed support structures 120 may be hardened. The hardening of the transformed support structures 120 may occur before the first and second solder balls 105 and 205 are melted.

Subsequently, the first and second solder balls 105 and 205 corresponding to each other may be melted and bonded to each other. Thus, the connection members 130 electrically connecting the first substrate 100 to the second substrate 200 may be formed. For example, each of the connection members 130 may be formed between a pair of the first connection pad 104 and the second connection pad 204 corresponding to or overlapping with each other in a plan view (e.g., along the direction orthogonal to the upper surface of the first substrate 100 facing the second substrate 200).

According to an exemplary embodiment of the present inventive concept, the second substrate 200 may be supported or fixed by the hardened support structures 120 between the first semiconductor chip 110 and the second substrate 200 while the first and second solder balls 105 and 205 are melted and bonded to each other. Thus, during the reflow process, warpage of the second substrate 200 may be reduced or eliminated and a non-wet defect between the first and second solder balls 105 and 205 may also be reduced or eliminated. In addition, a space having a substantially uniform height (e.g., in a range of about 20 μm to about 100 μm) may be secured between the first semiconductor chip 110 and the second substrate 200.

Referring to FIG. 5G, the first molding layer 140 may be formed between the first substrate 100 and the second substrate 200. The formation of the first molding layer 140 may include injecting a molding material into a space between the first and second substrates 100 and 200. The first molding layer 140 may cover the first semiconductor chip 110 and the connection members 130.

The first molding layer 140 may include the first portion 142 covering the connection members 130 and the second portion 144 filling the space between the first semiconductor chip 110 and the second substrate 200. The second portion 144 may cover sidewalls of the support structures 120.

According to an exemplary embodiment of the present inventive concept, since the space having the substantially uniform height (e.g., in the range of about 20 μm to about 100 μm) is secured between the first semiconductor chip 110 and the second substrate 200 by the support structures 120, the molding material may be evenly injected between the first semiconductor chip 110 and the second substrate 200. Thus, it is possible to reduce or eliminate an occurrence of a void (or an air gap) between the first semiconductor chip 110 and the second substrate 200.

In addition, according to an exemplary embodiment of the present inventive concept, the first molding layer 140 covering the connection members 130 and the first semiconductor chip 110 may be formed by a single process. Thus, the processes of manufacturing the semiconductor package may be simplified and manufacturing costs may be reduced.

When the underfill layer 150 is not formed (see, e.g., FIG. 5G), the first molding layer 140 may further include the third portion 146 filling the space between the first substrate 100 and the first semiconductor chip 110. The third portion 146 may cover the chip bumps 103. When the underfill layer 150 is formed, the first molding layer 140 need not include the third portion 146.

Referring again to FIG. 2A, external connection solder balls 107 may be formed on the external connection pads 106 of the first substrate 100, respectively.

FIG. 6 is a cross-sectional view illustrating a method for manufacturing a semiconductor package according to an exemplary embodiment of the present inventive concept. FIG. 6 is a cross-sectional view for explaining the reflow process performed in an exemplary embodiment of the present inventive concept in which the support structures include the polymer material having the glass transition temperature higher than the melting points of the first and second solder balls.

Referring to FIG. 6, the second substrate 200 may be positioned above the first substrate 100. Providing the first substrate 100, providing the second substrate 200, and mounting the first semiconductor chip 110 above the first substrate 100 may be performed by substantially the same methods as described with reference to FIGS. 5A to 5C.

The top surface of the first substrate 100 may face the bottom surface of the second substrate 200. The second solder balls 205 may correspond to or overlap with the first solder balls 105, respectively, when viewed in a plan view (e.g., along the direction orthogonal to the upper surface of the first substrate 100 facing the second substrate 200). In addition, the second solder balls 205 may be in contact with the first solder balls 105 corresponding thereto, respectively.

The support structures 120 may vertically overlap with the first semiconductor chip 110 along the direction orthogonal to the upper surface of the first substrate 100 facing the second substrate 200. As an example, the support structures 120 may overlap with the first semiconductor chip 110 when viewed in a plan view (e.g., along the direction orthogonal to the upper surface of the first substrate 100 facing the second substrate 200). For example, the thickness 120_TH of each of the support structures 120 along the direction orthogonal to the upper surface of the first substrate 100 facing the second substrate 200 may range from about 20 μm to about 100 μm.

In an exemplary embodiment of the present inventive concept, the support structures 120 may be vertically spaced apart from the first semiconductor chip 110 along the direction orthogonal to the upper surface of the first substrate 100 facing the second substrate 200 (see, e.g., FIG. 6). However, exemplary embodiments of the present inventive concept are not limited thereto. In an exemplary embodiment of the present inventive concept, the bottom surfaces of the support structures 120 may be in contact with the first semiconductor chip 110.

Referring to FIG. 5F, the connection members 130 electrically connecting the first substrate 100 to the second substrate 200 may be formed. The formation of the connection members 130 may include performing the reflow process to melt and bond each of the first solder balls 105 and each of the second solder balls 205 corresponding to each other. For example, each of the connection members 130 may be formed between a pair of the first connection pad 104 and the second connection pad 204 corresponding to or overlapping with each other in a plan view (e.g., along the direction orthogonal to the upper surface of the first substrate 100 facing the second substrate 200).

During the reflow process, the bottom surfaces of the support structures 120 may come into contact with the first semiconductor chip 110, and the support structures 120 might not be softened but may support or fix the second substrate 200. This may be because the support structures 120 include the polymer material having the glass transition temperature higher than the melting points of the first and second solder balls 105 and 205. Thus, during the reflow process, warpage of the second substrate 200 may be reduced or eliminated and a non-wet defect between the first and second solder balls 105 and 205 may also be reduced or eliminated. In addition, the space having the substantially uniform height along the direction orthogonal to the upper surface of the first substrate 100 facing the second substrate 200 (e.g., in the range of about 20 μm to about 100 μm) may be secured between the first semiconductor chip 110 and the second substrate 200.

Subsequent processes may be substantially the same as described with reference to FIGS. 5G and 2A.

According to an exemplary embodiment of the present inventive concept, the semiconductor package with increased reliability may be provided.

According to an exemplary embodiment of the present inventive concept, the method for manufacturing the semiconductor package with increased reliability may be provided.

According to an exemplary embodiment of the present inventive concept, the manufacturing processes of the semiconductor package may be simplified.

While the inventive concept has been particularly shown and described with reference to exemplary embodiments thereof, it will be understood by those of ordinary skill in the art that various changes in form and detail may be made therein without departing from the spirit and scope of the inventive concept.

1. A semiconductor package comprising:
a first semiconductor chip positioned above a first substrate;
a second substrate positioned above the first substrate, the first semiconductor chip positioned between the first substrate and the second substrate;
a plurality of support structures disposed between the second substrate and the first semiconductor chip;
connection members disposed between the first substrate and the second substrate, the connection members electrically connecting the first substrate to the second substrate; and
a molding layer filling a space between the first substrate and the second substrate, wherein the molding layer is disposed on the first semiconductor chip and the connection members.

2. The semiconductor package of claim 1, wherein the plurality of support structures are spaced apart from each other along a direction parallel to a surface of the first substrate facing the second substrate.

3. The semiconductor package of claim 2, wherein a minimum distance between the plurality of the support structures is about 300 μm or more.

4. The semiconductor package of claim 1, wherein a top surface of each of the plurality of support structures is in contact with the second substrate, and
wherein a bottom surface of each of the plurality of support structures is in contact with the first semiconductor chip.

5. The semiconductor package of claim 1, wherein the molding layer comprises:
a first portion covering sidewalls of the connection members; and
a second portion between the first semiconductor chip and the second substrate.

6. The semiconductor package of claim 5, wherein the second portion is positioned between support structures of the plurality of support structures.

7. The semiconductor package of claim 5, wherein the second portion is in contact with the second substrate and the first semiconductor chip.

8. The semiconductor package of claim 5, wherein the molding layer further comprises a third portion between the first substrate and the first semiconductor chip.

9. The semiconductor package of claim 1, further comprising:
an underfill layer between the first substrate and the first semiconductor chip.

10. The semiconductor package of claim 1, further comprising:
a third substrate positioned above the second substrate and electrically connected to the second substrate; and
a second semiconductor chip disposed on the third substrate.

11. The semiconductor package of claim 1, further comprising:
a second semiconductor chip disposed on the second substrate.

12. A semiconductor package comprising:
a first semiconductor chip positioned above a first substrate;
a second substrate positioned above the first substrate;
a support structure positioned between the second substrate and the first semiconductor chip;
a connection member electrically connecting the first substrate to the second substrate; and
a molding layer filling a space between the first substrate and the second substrate, wherein the molding layer is disposed on the first semiconductor chip and the connection member,
wherein a width of the support structure along a direction parallel to a surface of the first substrate facing the second substrate ranges from about 1/200 to about 1/10 of a width of the first semiconductor chip along the direction parallel to the surface of the first substrate facing the second substrate.

13. The semiconductor package of claim 12, wherein the width of the support structure ranges from about 30 μm to about 600 μm.

14. The semiconductor package of claim 12, wherein a thickness of the support structure along a direction orthogonal to the surface of the first substrate facing the second substrate ranges from about 1/10 to about ⅖ of a thickness of the connection member.

15. The semiconductor package of claim 12, wherein a thickness of the support structure along a direction orthogonal to the surface of the first substrate facing the second substrate ranges from about 20 μm to about 100 μm.

16. The semiconductor package of claim 12, wherein the support structure includes a polymer material.

17. The semiconductor package of claim 12, wherein a top surface of the support structure is in contact with the second substrate, and
wherein a bottom surface of the support structure is in contact with the first semiconductor chip.

18. The semiconductor package of claim 12, wherein the molding layer comprises:
a first portion covering a sidewall of the connection member, and
a second portion extending from the first portion into a space between the first semiconductor chip and the second substrate.

19. The semiconductor package of claim 18, wherein the second portion of the molding layer covers a sidewall of the support structure.

20-28. (canceled)

29. A semiconductor package comprising:
a first substrate;
a semiconductor chip positioned above the first substrate;
a second substrate positioned above the semiconductor chip;
a support structure disposed on an upper surface of the semiconductor chip facing the second substrate, wherein a bottom surface of the support structure is in direct contact with the upper surface of the semiconductor chip facing the second substrate, and wherein a top surface of the support structure is in direct contact with a bottom surface of the second substrate facing the semiconductor chip;
a plurality of connection members disposed between the first substrate and the second substrate, wherein at least one connection member of the plurality of connection members electrically connects the first substrate and the second substrate to each other; and
a molding layer formed between the first substrate and the second substrate, wherein the molding layer surrounds the semiconductor chip.

30. (canceled)
